(19) United States
(12) Patent Application Publication
(10) Pub. No.: US 2004/0145870 A1
(43) Pub. Date: Jul. 29, 2004

(54) Opening and closing device

(76) Inventors: Katsuichi Minami, Fukui (JP); Takehiko Konja, Fukui (JP); Masaki Nakase, Fukui (JP); Koji Sakai, Fukui (JP)

Correspondence Address: RATNERPRESTIA, P O BOX 980, VALLEY FORGE, PA, 19482-0980, US

(21) Appl. No.: 10/735,067

(22) Filed: Dec. 11, 2003

(30) Foreign Application Priority Data
Jan. 8, 2003 (JP) 2003-002042

(51) Int. Cl. H05K 5/00

(52) U.S. Cl. 361/724

(57) ABSTRACT

An opening and closing device includes a slide member in substantially ring shape placed in a contact area between a stator and a case, wherein a stator cam of the stator is elastically pushed by a rotor cam of a rotor elastically urged by a spring, wherein the case in substantially tubular shape accommodates the constituent members inside thereof, wherein the slide member serves as a lubricant element and reduces friction between the stator and the case, hence the opening and closing device is provided with a light operational feeling.

### TECHNICAL FIELD

This invention relates to an opening and closing device for used in a portable telephone, a small personal computer and other various electronic instruments.

### BACKGROUND OF THE INVENTION

Portable telephones, small personal computers and other electronic instruments have been recently compacted, light-weighted, and are given higher convenience, and an instrument having an openable and closable housing relative to a base housing, so called foldable type, is increasing. With this trend, an opening and closing device of easy open/close operation is required.

### SUMMARY OF THE INVENTION

It is an object of this invention to satisfy above-mentioned requests, and provide an opening and closing device which is handled with a light touch open/close operation and a smooth operational feeling.

To achieve above object, the opening and closing device in this invention includes a slide member in substantially ring shape placed in a contact area between a stator and a case, wherein a stator cam of the stator is pressed by a rotor cam of a rotor pushed by a spring, and the case in substantially tubular shape accommodates the constituent members. When the case is opened and closed, the slide member reduces friction between the stator and the case, allowing the opening and closing device to have the light touch open/close operation and the smooth operational feeling.

Additional objects and advantages of the present invention will be apparent from the following detailed description of preferred embodiments thereof, which are best understood with reference to the accompanying drawings.

### BRIEF DESCRIPTION OF THE DRAWINGS

FIG. 1 is a cross-sectional view of an opening and closing device in accordance with an exemplary embodiment of the present invention.

FIG. 2 is an exploded perspective view of the opening and closing device in accordance with the exemplary embodiment of the present invention.

FIG. 3 is a perspective view of an electronic device incorporating the opening and closing device in accordance with the exemplary embodiment of the present invention.

FIG. 4 is a cross-sectional view of an opening and closing device in accordance with other exemplary embodiments of the present invention.

FIG. 5 is a cross-sectional view of an opening and closing device in accordance with additional exemplary embodiments of the present invention.

FIG. 6 is a cross-sectional view of an opening and closing device.

FIG. 7 is an exploded perspective view of the opening and closing device.

### DESCRIPTION OF THE INVENTION

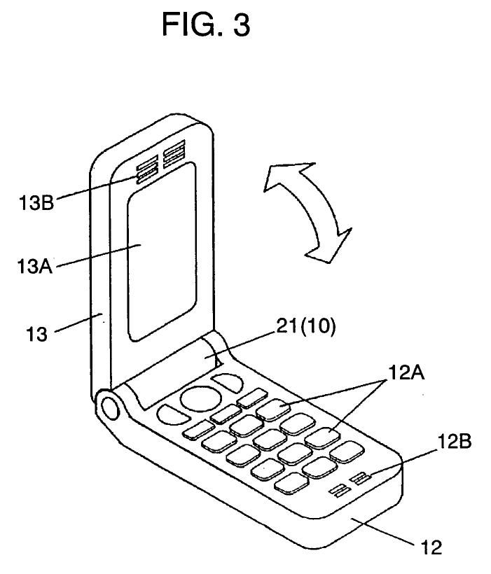

An opening and closing device 10 is described with reference to FIGS. 3, 5 and 6.

A cross-sectional view in the figures is elongated along a diameter of the device for explicitly demonstrating relation between a stator cam and a rotor cam.

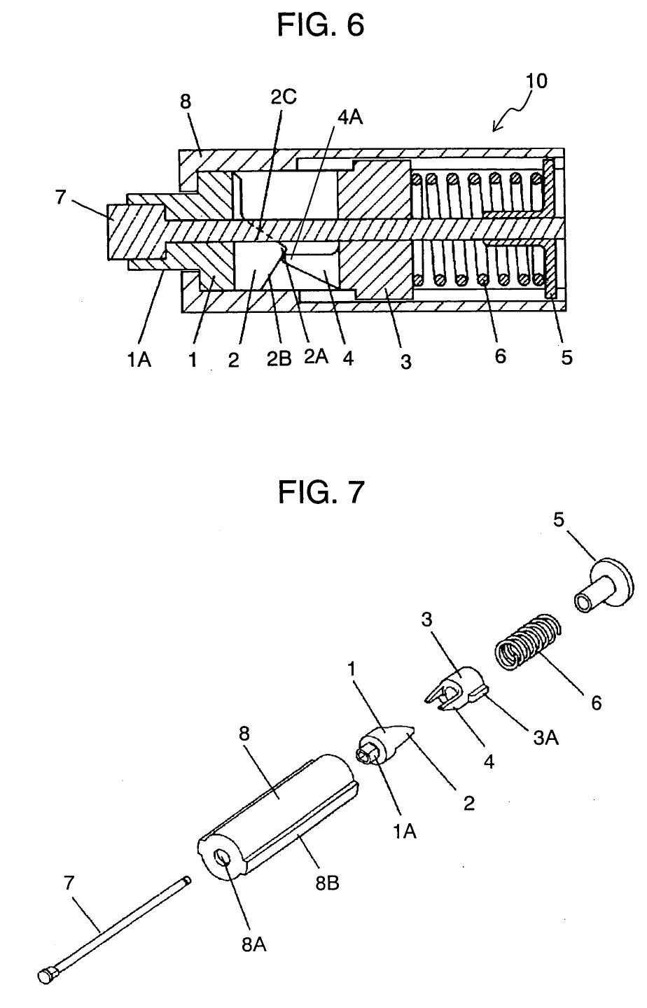

As shown in FIGS. 6 and 7, opening and closing device 10 includes stator 1 in substantially tubular shape having fix portion 1A at its left side face. Stator 1 has, at its right side outer periphery, stator cams 2 having tip portions 2A, and inclined portions 2B and 2C each extending toward left and right from tip portions 2A.

Rotor 3 in substantially tubular shape is rotatably disposed with respect to stator 1. Rotor 3 has rotor cams 4 at its left side outer periphery facing stator cams 2. Tip 4A of rotor cams 4 is elastically pressed to inclined portion 2B of stator cam 2 urged by spring 6 in coil shape interposed in a little contracted manner between rotor 3 and cover 5. Cover 5 is in substantially disc shape.

Fix shaft 7 in substantially cylindrical shape is fixed to stator 1 at its left end portion, and its right end portion is fix to cover 5 inserting through a hollow portion of rotor 3 and rotor spring 6.

Fix portion 1A of stator 1 is rotatably protruded from through-hole 8A formed at left end 8C of case 8 in substantially tubular shape. Grooves 8B is formed inside periphery of case 8 inserted by protrusion 3A of rotor 3, so that rotor 3 is movably accommodated in case 8 along an axis of the case.

Cover 5 coveres an opening portion at right end of case 8, and stator 1, rotor 3 and spring 6 are accommodated inside case 8. Thus, opening and closing device 10 is constituted.

Next, an example of conventional opening and closing device 10 as applied to a portable telephone is explained with reference to FIG. 3. In FIG. 3, fix portion 1A protruded from through-hole 8A at left end 8C (first end face) is attached to base housing 12, and case 8 is attached to foldable housing 13. Foldable housing 13 is rotatably equipped to base housing 12 with the opening and closing device, thus the portable telephone is constituted. Base housing 12 has operating portion 12A and includes a plurality of keys and voice input portion 12B such as a microphone on its upper surface. Foldable housing 13 has display portion 13A such as LCD and other voice input portion 13B such as a speaker on its surface.

As shown in FIG. 6, when tip 4A of rotor cam 4 is pressed to inclined portion 2B lower side of stator cam 2 by spring 6, rotor 3 is urged toward lower direction in FIG. 6, and the device is maintained in a closing condition. Therewith, foldable housing 13 fixed to case 8 is retained in the closing condition with regard to base housing 12.

When foldable housing 13 is manually opened from the closing condition, rotor 3 rotates around fix shaft 7 with case 8 fixed to foldable housing 13. As rotor 3 rotates, tip 4A of rotor cam 4 crosses over tip portion 2A of stator cam 2 and moves into inclined portion 2C upper side of the stator cam. Once tip 4A is moved to inclined portion 2C, tip 4A is kept pressed to inclined portion 2C by spring 6, so that rotor 3 is urged toward upper direction of an opening condition, and foldable housing 13 is retained in the opening condition. Namely, when foldable housing 13 is rotated from the closing condition to the opening condition, position of tip 4A of the rotor cam is moved from the lower side to the upper side of FIG. 6.

As described above, opening and closing device 10 is constituted so as to open and close foldable housing 13 with respect to base housing 12 by rotating case 8 fixed to foldable housing 13 thereby elastically pressing the tip of rotor cam 4 to one of inclined portions 2B and 2C of stator 1.

However, with opening and closing device 10, when case 8 is rotated with foldable housing 13 for opening and closing, a left face of stator 1 fixed to base housing 12 is pressed to the left inner end of case 8 by rotor 3 elastically urged by spring 6. For this reason, jerky feeling occurs with friction caused by open/close rotation of foldable housing 13, and operational feeling becomes worse.

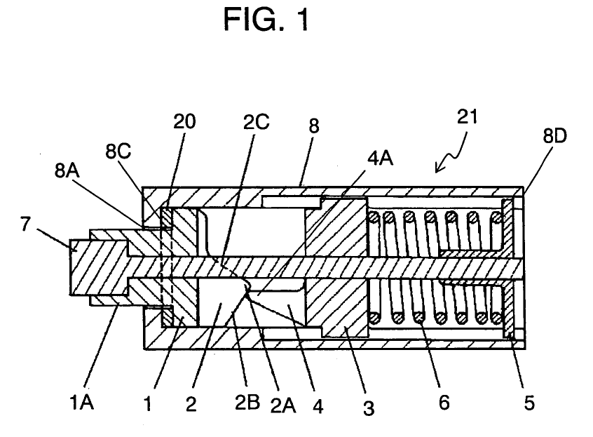

Exemplary embodiments of this invention are described hereinafter with reference to FIGS. 1 to 4.

As long as an element of this invention is similar to an element of opening and closing device 10, the same numbering is commonly applied, and detailed explanation is omitted.

A cross-sectional view illustrated in the figure is elongated in diameter of the device for explicitly demonstrating interaction between a stator cam and a rotor cam.

### EXEMPLARY EMBODIMENT 1

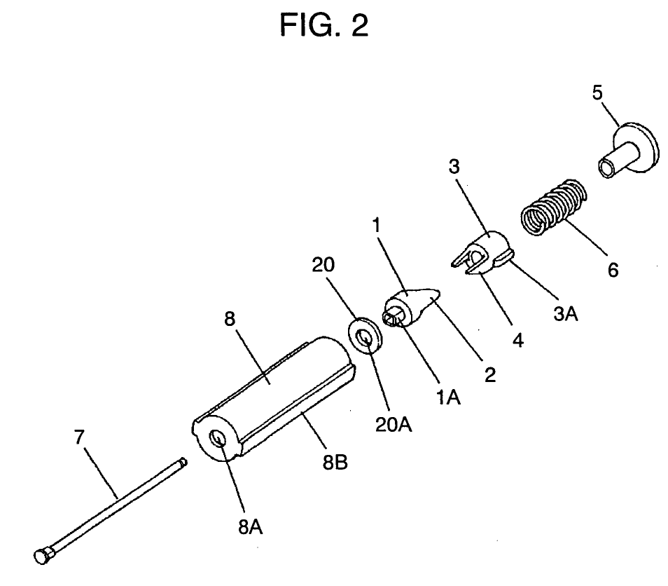

FIGS. 1 and 2 illustrate opening and closing device 21 in accordance with exemplary embodiment 1 of this invention. Opening and closing device 21 includes stator 1 in substantially tubular shape, made of metal, and having fix portion 1A at its left side face. Stator 1 has stator cams 2 along an outer periphery of its right side face, and stator cam 2 have tip portion 2A and inclined portions 2B and 2C each extending toward right and left from tip portion 2A.

The device 21 also includes rotor 3 in substantially tubular shape, made of metal, and rotatably disposed with respect to stator 1. Rotor 3 has rotor cams 4 along an outer periphery of left side face thereof, facing stator cams 2. Tip 4 A of rotor cam 4 is pressed to inclined portion 2B of stator cam 2, elastically pushed by spring 6 in coil shape which is interposed in a little contracted manner between rotor 3 and cover 5 in substantially disc shape.

Fix shaft 7 in substantially cylindrical shape is fixed to stator 1 at a left end portion of the shaft, and a right end portion of the shaft is rotatably attached to cover 5 inserted through a hollow portion of rotor 3 and spring 6. Fix portion 1A of stator 1 is rotatably protruded from through-hole 8A formed at left end 8C (first end face) of case 8 in substantially tubular shape, the case is made of metal or insulating resin.

Slide member 20 is interposed between the left side of stator 1 and case 8, wherein stator 1 is pressed to left end 8C of case 8 pushed by rotor 3 urged by spring 6. Slide member 20 has through-hole 20A in a center thereof, and fixed portion 1A of stator 1 is inserted through the hole. Namely, opening and closing device 21 in exemplary embodiment 1 has slide member 20 between stator 1 and case 8 facing each other, which is a remarkable difference from opening and closing device 10 in FIG. 5.

Slide member 20 has lubricity and can be a metal disk such as of copper and copper alloy in substantially ring shape, or a metal disk plated with lubricating material such as non-electrolyzed nickel-plating containing fluoride.

Protrusions 3A of rotor 3 are engaged with grooves 8B formed inside periphery of case 8, and rotor 3 is axially and slidably accommodated in case 8. Cover 5 is attached to a right end of case 8 and covers opening portion 8D (second opening end ) of case 8. Thus, opening and closing device 21 involves stator 1, slide member 20 and spring 6 in case 8, as described in exemplary embodiment 1.

Next, an example of opening and closing device 21 as applied to a portable telephone is explained with reference to FIG. 3. Fix portion 1A of stator 1 is fixed to base housing 12, and case 8 is fixed to foldable housing 13, therewith foldable housing 13 is openably and closably assembled to base housing 12 with opening and closing device 21, thus the portable telephone is constituted. Base housing 12 includes operating portion 12A having a plurality of keys, and voice input portion 13B such as a microphone on its upper surface. Foldable housing 13 includes display portion 13A such as LCD, a voice output portion 13B such as a speaker, on its face.

At first, opening and closing device 21 of this invention in a closing condition of the portable telephone is explained. In the closing condition as shown in FIG. 1, tip 4A of rotor cam 4 is pressed onto inclined portion 2B of stator cam 2 elastically pushed by spring 6. In this condition, rotor 3 pushed by spring 6 is urged downward in FIG. 1. Thereby, foldable housing 13 fixed to case 8 is retained in the closing condition with reference to base housing 12. The downward in FIG. 1 corresponds to a closing direction of opening and closing device 21.

When foldable housing 13 is manually opened from the closing condition, case 8 fixed to foldable housing 13 rotates and the rotor 3 rotates simultaneously around fixed shaft 7 with protrusion 3A engaged with groove 8B. When rotor 3 rotates, tip 4A of rotor cam 4 moves, crossing over tip portion 2A of stator cam 2, upwardly to inclined portion 2C. When the tip is moved to inclined portion 2C, rotor 3 is urged upward in FIG. 1 by spring 6, in an opening condition. Thereby, foldable housing 13 is retained in the opening condition.

With exemplary embodiment 1 of this invention, when case 8 is rotated, cover 5 and rotor 3 rotate simultaneously, therefore spring 6 interposed between cover 5 and rotor 3 also rotates at the same time. Hence, frictions are not caused either between spring 6 and cover 5 or between spring 6 and rotor 3. On the other hand, stator 1 which is fixed to base housing 12 at fixed portion 1A does not rotate, therefore, friction is expected to cause at a contact area between the left side surface of stator 1 and left end 8C (the first end face) of case 8. However, in the exemplary embodiment, slide member 20 is placed in the contact area for reducing the friction. Hence, jerky feeling is not occurred even when case 8 is rotated for opening and closing, and a smooth open/close operation is realized.

When foldable housing 13 is opened and closed, case 8 fixed to foldable housing 13 rotates, and during this process, spring 6 keeps pressing tip 4A of rotor cam 4 to one of inclined portions 2B and 2C of stator cam 2. Therefore, by interposing slide member 20 which reduces the friction between stator 1 and case 8, the light and smooth open/close operation is obtained even while the press force kept applied by spring 6.

As described, in the exemplary embodiment of this invention, the friction between stator 1 and case 8 is reduced by placing slide member 20 in substantially ring shape in the contact area between stator 1 and case 8, wherein spring 6 pushes rotor cam 4 of rotor 3 into stator cam 2 of stator 1, and case 8 in substantially tubular shape accommodates constituent members. With this construction, the opening and closing device with the smooth operation is obtained.

By forming slide member 20 with a metal plate of copper or alloy of copper, or with the metal plate plated with lubricating material such as non-electrolyzed nickel-plating containing fluoride, slide member 20 can be easily produced such as by stamping. By designing the slide member in substantially ring shape and by placing through-hole 20A in the center, a commercially available standard component such as a washer can be utilized, which makes component procurement easy and manufacturing of the opening and closing device less expensive.

Besides the metal plate or the metal plate plated with lubricating material, nylon and other high-density resin can be used for slide member 20, although molding process is necessary. By irradiating ultraviolet ray to resin dispersed with lubricant, cross-linked surface can be obtained by forming covalent bond of the molecules, which can be used for slide member 20. Molded part of sintered oil-contained-alloy can be used as well.

Instead of using slide member 20, stator 1 or case 8 can be above mentioned molded resin having lubricity. Applying lubricant plating on the contact area, lubricity can be given at least to one of stator 1 and case 8, which substitutes function of slide member 20 thereby a less expensive opening and closing device with smaller number of component can be provided.

In above exemplary embodiment of this invention, a constitution was explained wherein the opening portion at the right end of case 8 is closed by cover 5 and the right end portion of fixed shaft 7 is rotatably engaged with cover 5.

### EXEMPLARY EMBODIMENT 2

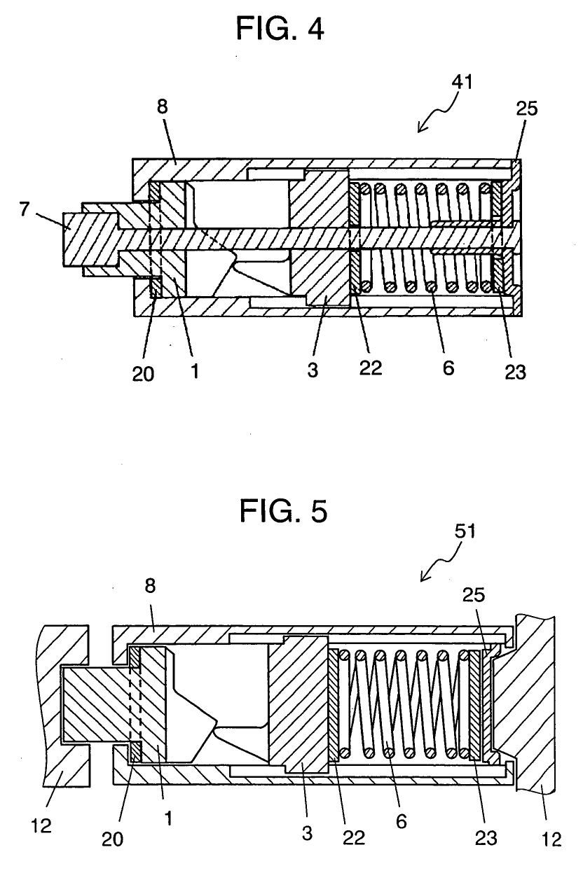

Opening and closing device 41 in exemplary embodiment 2 is shown in FIG. 4. Opening and closing device 41 includes cover 25 in substantially disc shape closing opening portion 8D (second opening end) at the right end of case 8. Cover 25 is fixed to the right end portion of fix shaft 7, and cover 25 is rotatably accommodated with reference to case 8. In exemplary embodiment 2 of this invention, when cover 8 is rotated, cover 25 and rotor 3 rotate together with case 8, thereby slide friction is caused between cover 25 and spring 6, and between rotor 3 and spring 6. Slide friction is also caused between stator 1 and case 8 as it was described in exemplary embodiment 1.

Opening and closing device 41 includes, in addition to slide member 20 placed in the contact area between stator 1 and case 8, slide member 22 in substantially ring shape placed in a contact area between rotor 3 and spring 6, and slide member 23 in substantially ring shape placed in a contact area between spring 6 and fix cover 25. By placing three lubricant slide members 20, 22 and 23, the friction between stator 1 and case 8, between spring 6 and rotor 3 and between spring 6 and cover 25 is reduced respectively. Hence, much lighter and smoother operation is realized with opening and closing device 41.

### EXEMPLARY EMBODIMENT 3

Opening and closing device 51 in exemplary embodiment 3 is shown in FIG. 5. It is a different from Opening and closing device 41 shown in FIG. 4 that the device 51 has no fix shaft 7. Stator 1 and cover 25 are directly fixed to base housing 12. Therefore, when case 8 and rotor 3 rotate, slide friction are caused between stator 1 and case 8, between spring 6 and between rotor 3 and spring 6 and cover 25 at the same time.

Opening and closing device 51 in exemplary embodiment 3 includes slide member 20 in substantially ring shape placed in the contact area between stator 1 and case 8, slide member 22 in substantially ring shape in the contact area between rotor 3 and spring 6, and slide member 23 in substantially ring shape placed in a contact area between spring 6 and cover 25. By placing three lubricant slide members 20, 22 and 23, the friction between stator 1 and case 8, between spring 6 and rotor 3 and between spring 6 and cover 25 is reduced respectively. Hence, much lighter and smoother operation is realized with opening and closing device 51.

Above explained is the opening and closing device of which foldable housing 13 is manually opened and closed thereby case 8 fixed to the foldable housing is rotated. The present invention can be applied, not only to above-mentioned structure, but also to so called a one-push-open type opening and closing device which has a function of one push opening in addition to the manual opening. The one-push-open type device includes a push button and a reverse rotor cam, in which the reverse rotor cam reverses elastically pressed position of stator cam 2, and foldable housing 13 in the closing condition is opened when the push button is pressed. The friction at time of opening and closing is reduced with this type as well.

As described, the present invention realizes the light and smooth opening and closing operation, and provides the opening and closing device having a light operational feeling.

It will be obvious to those skilled in the art that various changes may be made in the above-described embodiments of the present invention. However, the scope on the present invention should be determined by the following claims.

What is claimed is:

1. An opening and closing devise comprising:
a case in substantially tubular shape including a first end face having a first through-hole in a center thereof;
a stator facing the first end face inside the case;
a rotor accommodated in the case and facing the stator, the rotor being rotatable with respect to the stator;
a spring for pushing the rotor to the stator; and
a lubricant means placed between the stator and the first end face of the case.

2. The opening and closing device as defined in claim 1,
wherein the stator has a stator cam projected toward opposite to the first end face,
wherein the rotor has a rotor cam projected toward the stator,
wherein the spring pushes the rotor in a direction in which the rotor cam is contacted with the stator cam.

3. The opening and closing device as defined in claim 1,
wherein the lubricant means is a slide member interposed between the stator and the first end face of the case.

4. The opening and closing device as defined in claim 1, further comprising a cover for covering an opening of a second end face of the case,
wherein the cover is rotatable with respect to the case,
wherein the spring is interposed in a contracted manner between the cover and the rotor.

5. The opening and closing device as defined in claim 4,
wherein the lubricant means is a slide member interposed between the stator and the first end face of the case.

6. The opening and closing device as defined in claim 4,
wherein the device includes a second slide member between the spring and the rotor.

7. The opening and closing device as defined in claim 4, further comprising a third slide member between the spring and the cover.

8. The opening and closing device as defined in claim 4, further comprising a second slide member between the spring and the rotor, and a third slide member between the spring and the cover, wherein the lubricant mean is used as a first slide member.

9. The opening and closing device as defined in claim 4, further comprising a fix shaft,
wherein one end of the fix shaft is fixed to the stator, and an other end of the fix shaft is fixed to the cover.

10. The opening and closing device as defined in claim 1, further comprising a fix shaft, a cover for covering the opening of a second end face of the case,
wherein one end of the fix shaft is fixed to the stator, and an other end of the fix shaft is fixed to the cover.

11. The opening and closing device as defined in claim 3,
wherein the slide member is a metal plate having a lubricating surface.

12. The opening and closing device as defined in claim 8,
wherein at least one of the first slide member, the second slide member and the third slide member is a metal plate having a lubricating surface.

13. The opening and closing device as defined in claim 1,
wherein the lubricant means is a lubricant layer formed on a surface of at least one of the first end face and the stator facing the first end face.

14. The opening and closing device as defined in claim 1,
wherein the first end face of the case is formed of a molded member of lubricating material, and the first end face serves as the lubricant means.

15. The opening and closing device as defined in claim 1,
wherein the stator is formed of a molded member of lubricating material, and the stator serves as the lubricant means.
